(19) United States
(12) Patent Application Publication
(10) Pub. No.: US 2005/0029534 A1
(43) Pub. Date: Feb. 10, 2005

(54) Semiconductor device and method of manufacturing the same

(76) Inventors: Isao Ochiai, Gunma (JP); Makoto Tsubonoya, Gunma (JP); Katsuhiko Shibusawa, Gunma (JP); Takanori Kato, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/899,219

(22) Filed: Jul. 26, 2004

(30) Foreign Application Priority Data
Jul. 31, 2003 (JP) P2003-204296

(51) Int. Cl. H01L 33/00

(52) U.S. Cl. 257/99

(57) ABSTRACT

A semiconductor device of the present invention has a semiconductor element mounted on a surface of a support substrate, a case member for covering the surface of the support substrate to seal the semiconductor element, fine metal wires as connecting region for electrically connecting the semiconductor element and external terminals extending outside, and a frame member as a fixing component for mechanically fixing the semiconductor element to the support substrate by coming into contact with side surfaces of the semiconductor element.

Priority is claimed to Japanese Patent Application Number JP2003-204296 filed on Jul. 31, 2003, the disclosure of which is incorporated herein by reference in its entirety.

### BACKGROUND OF THE INVENTION

1. Field of the Invention

The present invention relates to a semiconductor device in which a mechanically fixed semiconductor element is incorporated, and relates to a method of manufacturing the same.

2. Description of the Related Art

With reference to FIG. 8, a semiconductor device 100 of a conventional type will be described. FIG. 8 is a perspective view of the semiconductor device 100 of the conventional type.

Referring to this drawing, in the semiconductor device 100 of the conventional type, a lead 104 at a center has an island 102 in an end thereof. Further, a semiconductor element 101 is fixed to a top of the island 102 by way of adhering means such as solder. There are leads 104 on opposite sides of the island 102. The semiconductor element 101 is electrically connected to the leads 104 through fine metal wires 105. Moreover, except for portions of the leads 104 which become external terminals, the above-described components are sealed with sealing resin 106

However, in the aforementioned semiconductor device 100, the semiconductor element 101 is thermally affected from outside through the sealing resin 106 or the leads 104. Accordingly, there is a problem in which a change in temperature of outside air adversely affects operation of the semiconductor element 101. Furthermore, if the semiconductor element 101 is fixed by way of a soldering material such as solder, there is a problem in which characteristics of the semiconductor element 101 are changed by high temperature in fixing.

### SUMMARY OF THE INVENTION

The preferred embodiments of the present invention have been accomplished in light of the above-described problems. A major object of the preferred embodiments is to provide a semiconductor device in which a semiconductor element thermally insulated from outside is incorporated, and to provide a method of manufacturing the same.

A preferred embodiment of the present invention comprises a semiconductor element mounted on a surface of a support substrate; a case member for covering the surface of the support substrate to seal the semiconductor element; connecting region for electrically connecting the semiconductor element and an external terminal extending to the outside; and a fixing component for mechanically fixing the semiconductor element to the support substrate by coming into contact with side surfaces of the semiconductor element.

Furthermore, a preferred embodiment of the present invention comprises: fixing a fixing component to a support substrate; fixing the semiconductor element to the support substrate by bringing the fixing component into contact with side surfaces of the semiconductor element; electrically connecting the semiconductor element and the external terminal extending to the outside; and covering the surface of the support substrate with the case member to seal the semiconductor element in an atmosphere in which pressure is lower than atmospheric pressure.

### BRIEF DESCRIPTION OF THE DRAWINGS

FIG. 1A is a plan view, FIG. 1B is a cross-sectional view, and FIG. 1C is a cross-sectional view showing a semiconductor device of an embodiment.

FIGS. 2A to 2D are plan views of a frame member as a fixing component used in the semiconductor device of an embodiment.

FIG. 3A is a plan view, FIG. 3B is a cross-sectional view, and FIG. 3C is a cross-sectional view showing the semiconductor device of an embodiment.

FIG. 4A is a plan view, FIG. 4B is a cross-sectional view, and FIG. 4C is a cross-sectional view showing the semiconductor device of an embodiment.

FIGS. 5A is a plan view and FIG. 5B is a cross-sectional view showing a method of manufacturing the semiconductor device of a embodiment.

FIG. 6A is a plan view and FIG. 6B is a cross-sectional view showing the method of manufacturing the semiconductor device of an embodiment.

FIG. 7 is a cross-sectional view showing the method of manufacturing the semiconductor device of an embodiment.

FIG. 8 is a perspective view showing a conventional semiconductor device.

### DESCRIPTION OF THE PREFERRED EMBODIMENTS

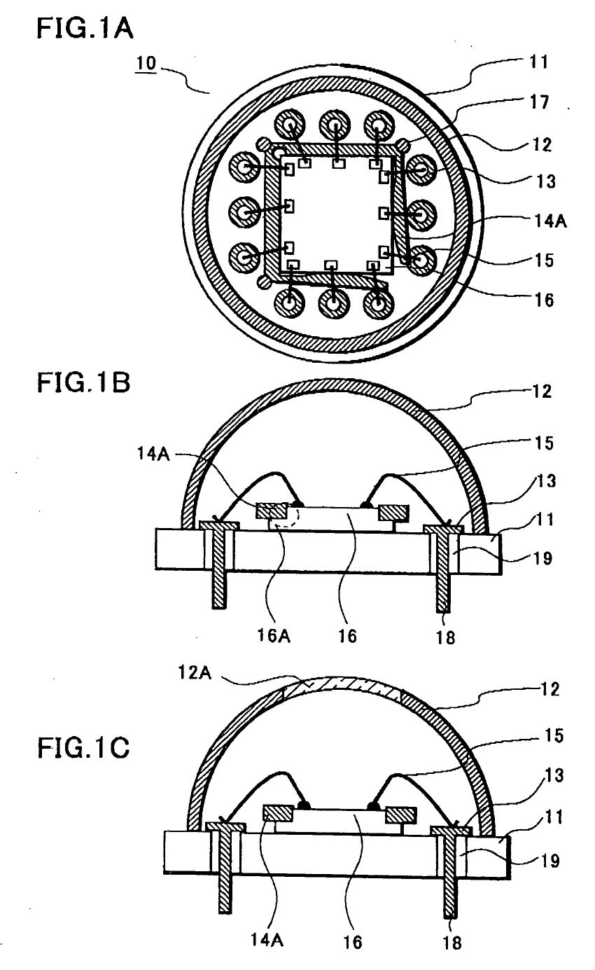

The specific structure of a semiconductor device 10 of a preferred embodiment will be described with reference to FIGS. 1A to 1C. FIG. 1A is a plan view of the semiconductor device 10, and FIGS. 1B and 1C are cross-sectional views thereof.

Referring to FIGS. 1A and 1B, the semiconductor device 10 of the preferred embodiment has a semiconductor element 16 mounted on a surface of a support substrate 11, a case member 12 for covering the surface of the support substrate 11 so that the semiconductor element 16 is sealed, fine metal wires 15 as connecting means for electrically connecting the semiconductor element 16 with external terminals 18 extending outside, and a frame member 14A as a fixing component for mechanically fixing the semiconductor element 16 to the support substrate by coming into contact with side surfaces of the semiconductor element 16. Each of these components will be described in detail below.

The support substrate 11 is made of metal. On the surface of the support substrate 11, the semiconductor element 16 is mounted. Further, a plurality of pads 13 continuous with the external terminals 18 are formed in a periphery of a region where the semiconductor element 16 is mounted. The support substrate 11 has a circular shape here, but may have another shape such as a rectangular shape. Moreover, a material other than metal can be also adopted as a material for the support substrate 11. Glass, ceramic, resin material, or the like can also be adopted.

The semiconductor element 16, on a surface of which a desired electric circuit is formed, is placed in the vicinity of a center of the support substrate 11. Further, the semiconductor element 16 and the pads 13 are electrically connected through the fine metal wires 15. Moreover, the semiconductor element 16 is mechanically fixed to the support substrate 11 by means of the frame member 14A as the fixing component. Furthermore, in order to improve the heat insulation with the outside, a back surface of the semiconductor element 16 may be located apart from the support substrate 11.

The case member 12 is made of metal, and covers the surface of the support substrate 11 so as to cover the semiconductor element 16, the fine metal wires 15, the pads 13, and the frame member 14A. Specifically, the case member 12 has an almost hemispherical shape with a curved surface, and is joined to the periphery of the discoid support substrate 11. Moreover, in the case where both the case member 12 and the support substrate 11 are made of metal, they can be bonded together by welding. Furthermore, a material other than metal can be also adopted as a material for the case member 12. Glass, ceramic, resin material, or the like can be also adopted.

Air pressure in an internal space formed by the case member 12 and the support substrate 11 is lower than outside atmospheric pressure. Specifically, the air pressure in this internal space can be set at very low air pressure of approximately 1×10⁻⁵ Torr. In the case where the air pressure of the internal space is lower than atmospheric pressure as described above, high pressure from the outside acts on the case member 12. However, it is possible to impart stress against air pressure to the case member 12 by forming the case member 12 into a hemispherical shape as shown in the drawing. Moreover, the semiconductor element 16 incorporated into the internal space can be thermally isolated from the outside by setting the internal space to high vacuum as described above. That is, the internal space of the semiconductor device 10 is at an almost constant temperature even if the temperature of the outside changes. Accordingly, operation of the semiconductor element 16 can be stabilized.

The frame member 14A has a function of mechanically fixing the semiconductor element 16 to the support substrate 11. Specifically, the frame member 14A fixes the semiconductor element 16 to the support substrate 11 by coming into contact with the side surfaces of the semiconductor element 16 using elasticity of the frame member 14A. Here, the frame member 14A is made of metal, and three corners of the frame member 14A are fixed to the support substrate 11 using a join mechanism such as welding or the like.

The merit of using the frame member 14A for fixing the semiconductor element 16 will be described. General semiconductor element-fixing methods include a fixing method using an organic adhesive such as epoxy resin, and a fixing method using a soldering material such as solder. However, in the fixing method using an organic adhesive such as epoxy resin, the organic adhesive evaporates at room temperature in the internal space under high vacuum to increase the air pressure in the internal space. This impairs thermal insulation between outside air and the semiconductor element 16 and destabilizes the operation of the semiconductor element 16. On the other hand, in the fixing method using the soldering material such as solder, the semiconductor element 16 is heated in a reflow step, and therefore there is a risk that the sensitivity of the semiconductor element 16 may change. With a fixing mechanism of the semiconductor element 16 by use of the frame member 14A of the preferred embodiment, an organic adhesive, which has a risk of evaporating, is not used, and further, fixing can be performed without heating. Accordingly, it is possible to provide a mechanism and a method for stably fixing the semiconductor element 16.

The fixing mechanism of the semiconductor element 16 by use of the frame member 14A will be described in more detail with reference to FIG. 1B. In the periphery of the semiconductor element 16, step portions 16A are provided. Further, the frame member 14A is in contact with flat portions and side surface portions of the step portions 16A. Thus, the frame member 14A comes into contact with the step portions 16A provided in the periphery of the semiconductor element 16, whereby the semiconductor element 16 can be fixed in both the longitudinal and lateral directions.

The external terminals 18 are made of a conductive material, penetrate the support substrate 11 to continuously extend from the pads 13 to the outside, and have a function of performing electrical input from, and output to, the outside. Accordingly, the external terminals 18 are electrically connected to the semiconductor element 16 through the pads 13 and the fine metal wires 15. Further, a gap between each external terminal 18 and the support substrate 11 is filled with filler 19 in order to prevent outside air from entering the internal space. Furthermore, in the case where the support substrate 11 is made of metal, electrical short circuits between the support substrate 11 and the external terminals 18 can be prevented by adopting an insulating material as the filler 19. More preferably, low-temperature glass is adopted as the filler 19, there by making it possible to prevent the filler 19 from evaporating due to the high vacuum of the internal space. Moreover, low-temperature glass is excellent in workability because of a low melting point thereof.

The structure of the semiconductor device 10 of another embodiment will be described with reference to FIG. 1C. In this case, a semiconductor element having a light-receiving section or a light-emitting section on the surface thereof is adopted as the semiconductor element 16. Specifically, a semiconductor element which receives or emits a visible ray, an infrared ray, or the like is adopted as the semiconductor element 16 in this case.

A portion of the case member 12 which corresponds to an upper side of the semiconductor element 16 is a transparent portion 12A made of a transparent material. The transparent portion 12A is made of, for example, glass, and has a shape in which a curved surface continuous with the case member 12 is formed. The transparent portion 12A is made of a material which is transparent to light emitted or received by the semiconductor element 16.

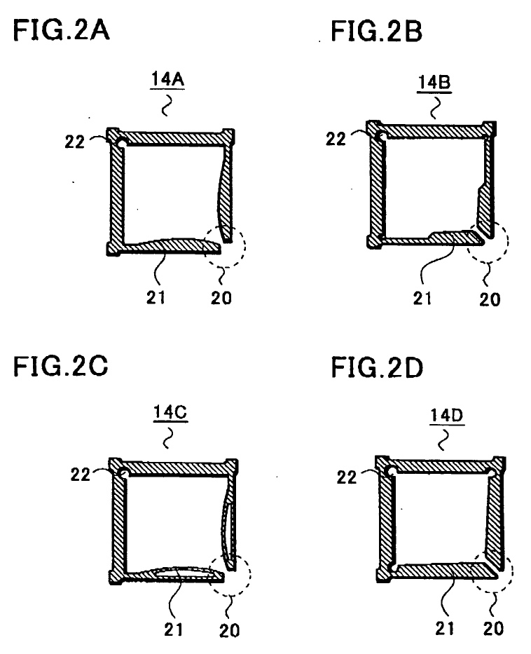

With reference to FIGS. 2A to 2D, frame members 14 for fixing the semiconductor element 16 will be described in detail. FIGS. 2A to 2D are plan views showing shapes of the frame members 14 of respective embodiments.

Referring to FIG. 2A, the frame member 14A has an almost picture frame-like shape. An inner size of the frame member 14A is equal to or less than that of the semiconductor element 16. Further, in the frame member 14A, an opening portion 20 is provided by cutting off one corner. Inwardly protruding convex portions 21 are formed on the two sides adjacent to the opening portion 20, respectively. The convex portions 21 in this case inwardly protrude in arcs, respectively. Accordingly, the convex portions 21 softly come into contact with the side surfaces of the semiconductor element 16. A notched portion 22 cut off into a circle is formed in an inner corner opposite to the opening portion 20. This promotes elastic deformation of the frame member 14A in the plane direction.

With reference to FIG. 2B, a shape of a frame member 14B of another embodiment will be described. The basic shape of the frame member 14B is the same as that of the frame member 14A. The difference between them is the shape of the convex portions 21. Specifically, the convex portions 21 in this case are provided in parts of sides which are closer to the opening portion 20. Furthermore, parts of the convex portions 21 which come into contact with the side surfaces of the semiconductor element 16 are formed to be flat, thus making it possible to increase areas of the parts of the convex portions 21 which come into contact with the side surfaces of the semiconductor element 16.

With reference to FIG. 2C, a shape of a frame member 14C of another embodiment will be described. The basic shape of the frame member 14C is the same as that of the frame member 14A. The difference between them is the shape of the convex portions 21. Specifically, the frame member 14C has a shape in which the convex portions 21 are partially hollowed out. Accordingly, weight of the frame member 14C can be reduced.

With reference to FIG. 2D, a shape of a frame member 14D of another embodiment will be described. The basic shape of the frame member 14D is the same as that of the frame member 14A. The difference between them is the shape of the convex portions 21. In this case, an internal shape of each convex portion 21 is a linear shape extending over the most part of the relevant side. Accordingly, the area of the region of the convex portion 21 which comes into contact with the semiconductor element 16 increases. Moreover, in this case, notched portions 22 are formed in three corners of the frame member 14D. Accordingly, the elastic deformation of the frame member 14D in the plane direction is further promoted.

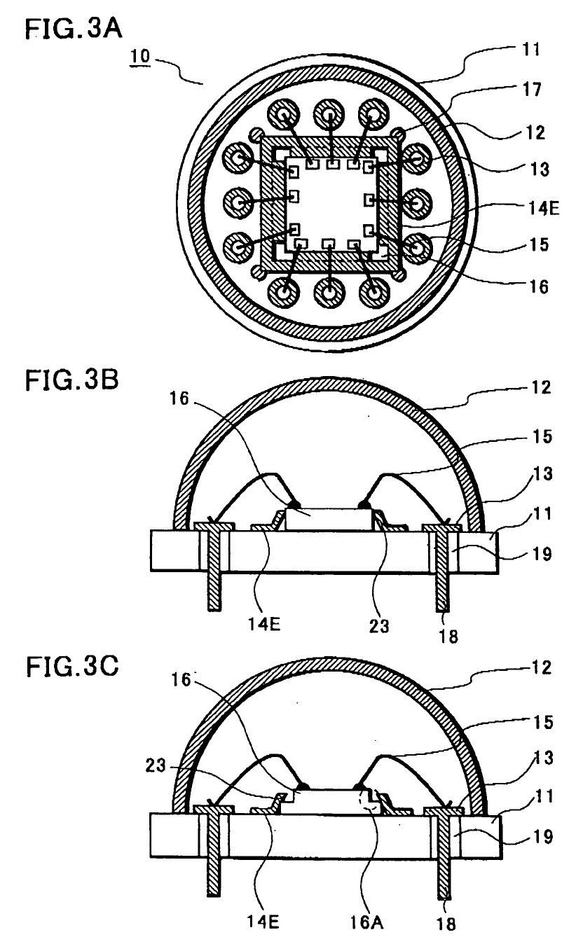

With reference to FIGS. 3A to 3C, structures of the semiconductor device 10 having other fixing mechanisms of the semiconductor element 16 will be described. FIG. 3A is a plan view of the semiconductor device 10. FIGS. 3B and 3C are cross-sectional views of the semiconductor device 10.

Referring to FIGS. 3A and 3B, the basic structure of the semiconductor device 10 shown in these drawings is the same as that shown in FIGS. 1A and 1B. The difference between them is the fixing mechanism of the semiconductor element 16. Specifically, a frame member 14E in this case has a closed picture frame-like shape, and contact portions 23 inwardly extend from four sides of the frame member 14E. The contact portions 23 inwardly extend, and bend upward halfway. Thus, edges of the contact portions 23 bending upward come into contact with the side surfaces of the semiconductor element 16, whereby the semiconductor element 16 is fixed to the support substrate 11.

Referring to FIG. 3C, the step portions 16A are formed in the periphery of the semiconductor element 16. Further, the contact portions 23 are in contact with the step portions 16A. Accordingly, the power of fixing the semiconductor element 16 is further improved.

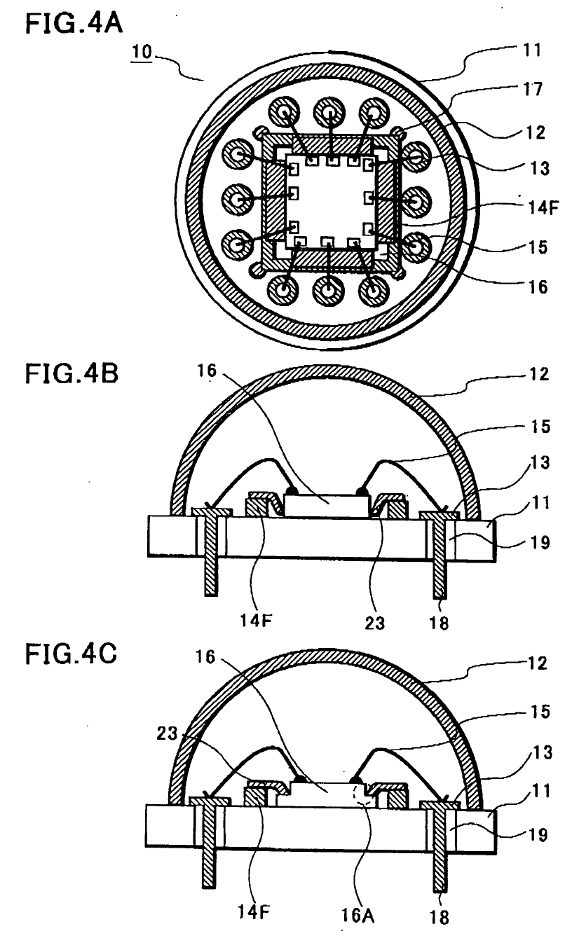

With reference to FIGS. 4A to 4C, structures of the semiconductor device 10 having still other fixing mechanisms of the semiconductor element 16 will be described. FIG. 4A is a plan view of the semiconductor device 10. FIGS. 4B and 4C are cross-sectional views of the semiconductor device 10.

Referring to FIGS. 4A and 4B, the basic structure of the semiconductor device 10 shown in these drawings is the same as that shown in FIGS. 1A and 1B. The difference between them is the fixing mechanism of the semiconductor element 16. Specifically, a frame member 14F in this case has a closed picture frame-like shape, and the contact portions 23 inwardly extend from the four sides of the frame member 14F. The contact portions 23 in this case are fixed to a top of the frame member 14F. Cross-sectionally, the contact portions 23 inwardly extend and are bowed obliquely downward. The edges of the contact portions 23 come into contact with the side surfaces of the semiconductor element 16, whereby the semiconductor element 16 is fixed to the support substrate 11. Further, four corners of the frame member 14F are fixed to the support substrate 11 by welding, soldering, or the like.

Referring to FIG. 4C, the step portions 16A are formed in the periphery of the semiconductor element 16. Further, the contact portions 23 are in contact with the step portions 16A. Accordingly, the power of fixing the semiconductor element 16 is further improved.

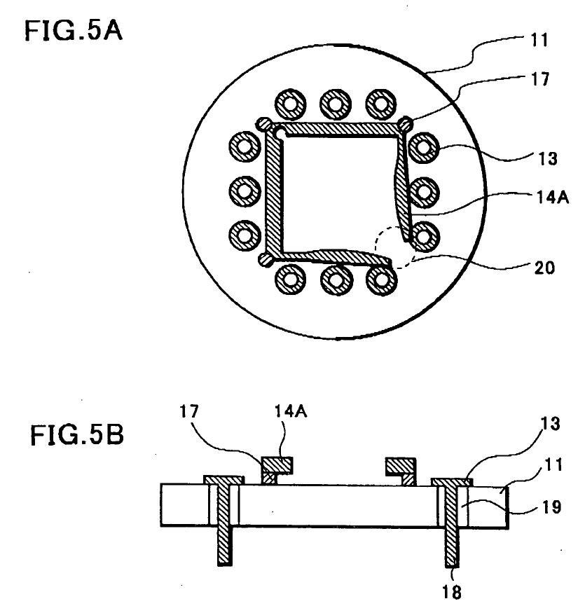

A method of manufacturing the above-described semiconductor device 10 will be described with reference to FIGS. 5A and 5B and subsequent drawings. The method of manufacturing the semiconductor device 10 has the steps of: fixing a frame member 14 to the support substrate 11; fixing the semiconductor element 16 to the support substrate 11 by bringing the frame member 14 into contact with the side surfaces of the semiconductor element 16; electrically connecting the semiconductor element 16 and the external terminals 18 extending to the outside; and covering the surface of the support substrate 11 with the case member to seal the semiconductor element 16 in an atmosphere in which pressure is lower than atmospheric pressure. Each of these steps will be described in detail below.

With reference to FIGS. 5A and 5B, the step of fixing the frame member 14 to the support substrate 11 will be described. FIG. 5A is a plan view of this step, and FIG. 5B is a cross-sectional view of this step.

Referring to FIGS. 5A and 5B, the frame member 14 is fixed to the support substrate 19 by use of fixing portions 17 fixed to the support substrate 11 by spot welding, soldering, or the like. As the frame member 14 shown in these drawings, one having the opening portion 20 as shown in FIGS. 2A to 2D is adopted. Accordingly, in this case, three corners of the frame member 14, except for the corner in which the opening portion 20 is provided, are fixed by use of the above-described fixing portions 17.

Moreover, the plurality of pads 13 made of a conductive material are formed in a region of the support substrate 11 which is outside the frame member 14. Further, the pads 13 are electrically connected to the external terminals 18 extending to the outside of the device, respectively.

Furthermore, referring to FIG. 5B, the frame member 14 is fixed to the support substrate 11 in a state where the frame member 14 is located apart from the support substrate 11. Such a structure makes it possible to more reliably fix the semiconductor element 16 having step portions as shown in FIG. 1B.

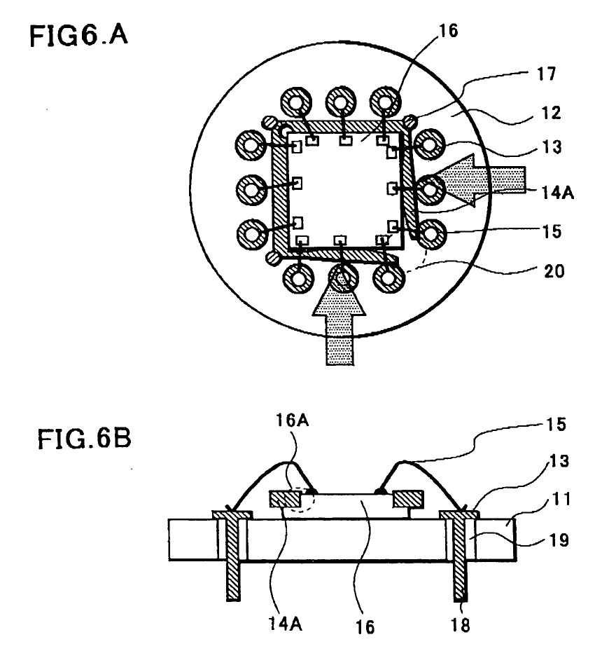

Next, referring to FIGS. 6A and 6B, the semiconductor element 16 is fixed to the support substrate 11 by bringing the frame member 14 into contact with the side surfaces of the semiconductor element 16. FIG. 6A is a plan view of this step, and FIG. 6B is a cross-sectional view of this step.

Referring to FIG. 6A, after the two sides of the frame member 14 which are adjacent to the opening portion 20 have been outwardly pushed open, the semiconductor element 16 is mounted inside the frame member 14. Then, the sides of the frame member 14 which have been outwardly pushed open are brought back to the original state. This allows pressure (tension) to act from the two sides of the frame member 14 in the directions of the arrows shown in this drawing. Thus, the semiconductor element 16 is fixed by the frame member 14. Accordingly, die bonding of the semiconductor element 16 is performed without any die attach adhesive such as an organic adhesive, and without heat treatment such as a reflow step. After the fixing of the semiconductor element 16 has been finished, the semiconductor element 16 is electrically connected to the pads 13 through the fine metal wires 15.

Referring to FIG. 6B, the frame member 14 is in contact with the step portions 16A provided in the periphery of the semiconductor element 16. Thus, the frame member 14 comes into contact with the step portions 16A, whereby the semiconductor element 16 is fixed in both the longitudinal and lateral directions.

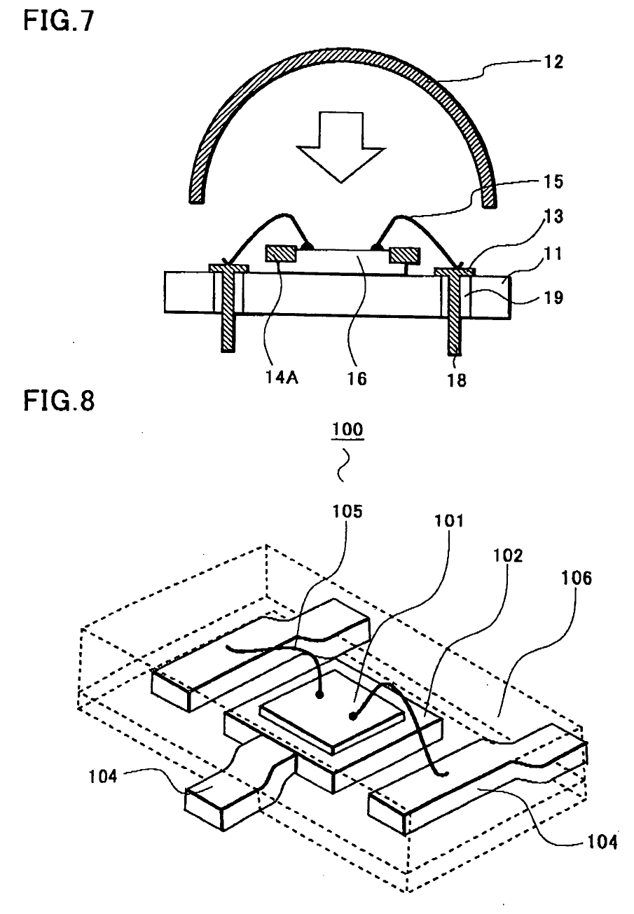

Next, referring to FIG. 7, the surface of the support substrate 11 is covered with the case member so that the semiconductor element 16 is sealed in an atmosphere in which pressure is lower than atmospheric pressure. FIG. 7 is a cross-sectional view showing the state of this step.

In this step, the case member 12 and the support substrate 11 are joined under high vacuum to seal the semiconductor element 16 and the like. The high vacuum in this case is at an air pressure of, for example, approximately 1×10⁻⁵ Torr, and conduction of heat through the relevant space can be significantly reduced. Further, the work of this step is performed under the above-described high vacuum. The case member 12 and the support substrate 11 can be connected by welding in the case where both of them are metal. Alternatively, they can also be joined by using a soldering material such as solder.

The above-described steps provide the semiconductor device 10 having a structure as shown in, for example, FIGS. 1A and 1B.

The preferred embodiments of the present invention have the following effects.

The semiconductor element 16 is mechanically fixed to the support substrate 11. Further, the semiconductor element 16 is sealed in the internal space under high vacuum which is formed by the case member 12 and the support substrate 11. Accordingly, the semiconductor element 16 is fixed to the support substrate 11 without an organic adhesive or the like, which evaporates under high vacuum. Consequently, the structure of the semiconductor device in which the high vacuum of the internal space is maintained can be provided. This makes it possible to achieve a high degree of thermal insulation between the semiconductor element 16 and the outside of the device. Accordingly, the operation of the semiconductor element 16 can be stabilized.

Moreover, the semiconductor element 16 can be fixed by use of the frame member 14 as the fixing component. Accordingly, it is possible to. provide the method of manufacturing the semiconductor device in which a heating step, such as a reflow step in the case where solder or the like is used, is omitted.

1. A semiconductor device comprising:
a semiconductor element mounted on a surface of a support substrate;
a case member for covering the surface of the support substrate to seal the semiconductor element;
a connecting region for electrically connecting the semiconductor element and an external terminal extending outside; and
a fixing component for mechanically fixing the semiconductor element to the support substrate by coming into contact with side surfaces of the semiconductor element.

2. The semiconductor device according to claim 1, wherein the fixing component is a frame member having a shape of a frame in which one corner is cut off, the frame member is fixed to the support substrate, and four inner sides of the frame member fix the semiconductor element to the support substrate by coming into contact with the side surfaces of the semiconductor element.

3. The semiconductor device according to claim 2, wherein an inner size of the frame member is equal to or less than that of the semiconductor element.

4. The semiconductor device according to claim 2, wherein the frame member has inwardly protruding convex portions on the two sides continuous with the cut-off corner, and the convex portions fix the semiconductor element to the support substrate by coming into contact with the side surfaces of the semiconductor element.

5. The semiconductor device according to claim 1, wherein the fixing component is made of metal, and the semiconductor element is fixed to the support substrate using elasticity of the fixing component.

6. The semiconductor device according to claim 1, wherein pressure in a space sealed with the support substrate and the case member is lower than atmospheric pressure.

7. The semiconductor device according to claim 1, wherein the semiconductor element has either a right-receiving section or a right-emitting section on a surface thereof, and a portion of the case member which is above the semiconductor element is made either of a material which is transparent to light emitted by the semiconductor element or a material which is transparent to light received by the semiconductor element.

8. The semiconductor device according to claim 1, wherein step portions are provided in a periphery of the semiconductor element, and the fixing component comes into contact with the step portions.

9. The semiconductor device according to claim 1, wherein the fixing component comprises: a frame member having a shape of a frame; and contact portions inwardly extending from the frame member, wherein the contact portions fix the semiconductor element to the support substrate by coming into contact with the side surfaces of the semiconductor element.

10. The semiconductor device according to claim 9, wherein step portions are provided in a periphery of the semiconductor element, and the contact portions come into contact with the step portions.

11. A method of manufacturing a semiconductor device, comprising:
fixing a fixing component to a support substrate;
fixing a semiconductor element to the support substrate by bringing the fixing component into contact with side surfaces of the semiconductor element;
electrically connecting the semiconductor element and an external terminal extending outside; and
covering a surface of the support substrate with a case member to seal the semiconductor element in an atmosphere in which pressure is lower than atmospheric pressure.

12. The method of manufacturing the semiconductor device according to claim 11, wherein the support substrate and the case member are made of metal and integrated by welding.
